(19) United States
(12) Patent Application Publication
(10) Pub. No.: US 2007/0082490 A1
(43) Pub. Date: Apr. 12, 2007

(54) APPARATUS OF CHEMICAL MECHANICAL POLISHING AND CHEMICAL MECHANICAL POLISHING PROCESS

(76) Inventors: Chun-Ting Hu, Hsinchu City (TW); Chu-Yi Hsieh, Hsinchu City (TW); Tzu-Yu Tseng, Kaohsiung City (TW); Yung-Chieh Kuo, Hsinchu County (TW); Hung-Chi Pai, Nantou County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,132

(22) Filed: Oct. 6, 2005

(51) Int. Cl. H01L 21/302; H01L 21/461; H01L 29/788

(52) U.S. Cl. 438/691; 257/315

(57) ABSTRACT

An apparatus of chemical mechanical polishing has a polishing machine, a first thickness metrology and a second thickness metrology. The first thickness metrology is connected with the polishing machine, and the second thickness metrology is connected with the polishing machine. Since the thickness of the first material layer and the second material layer after polishing process can be separately measured by the first thickness metrology and the second thickness metrology in-situ, the difference of film thickness between wafers can be reduced.

### BACKGROUND OF THE INVENTION

1. Field of Invention

The present invention relates to apparatus and fabrication in semiconductor apparatus and semiconductor fabrication. More particularly, the present invention relates to a chemical mechanical polishing (CMP) apparatus and the CMP process.

2. Description of Related Art

The CMP process is a common technology used in layer planarization. The CMP process uses the slurry with floating abrasive particles and the polishing pad with proper elasticity and hardness, so as to achieve the planarizing effect by the relative motion between the polishing pad and the wafer surface.

The application of CMP process is rather wide. For example, one application is for fabricating interconnect structure. In the process for forming the metal interconnect structure, an opening is first formed in the dielectric layer by etching, and then, a lining layer is formed over the opening and the dielectric surface. Then, a metal layer is formed over the lining layer and fills the opening. The CMP process is then used to remove a portion of the metal layer and the lining layer other than the opening. As a result, an interconnect structure is formed in the opening.

In order to effectively control the resistance of the interconnect structure, after the CMP process accomplishes for the wafers in one lot, a thickness measuring apparatus is used to measure the thickness of the remaining metal layer or the dielectric layer on the wafers. The measured result is fed back and is used as the reference for the CMP process on the wafers in next lot. However, since the measurements for the metal layer or the dielectric layer should be performed at another machine, that is, only when the wafers of the lot are polished in completion, the measurement then is performed. Therefore, the foregoing thickness measurement is only for controlling the thickness difference for lot to lot. However, for the wafers in one lot, the thickness difference between each wafer cannot be effectively controlled by this measurement. As a result, it causes the issue of non-uniform resistance of the metal layer on each wafer.

### SUMMARY OF THE INVENTION

In an objective, the invention provides a CMP apparatus, for solving the issues of non-uniform thickness for each wafer.

In another objective, the invention provides a CMP process, for solving the issues of non-uniform thickness for each wafer.

The invention provides a CMP apparatus. The CMP apparatus at least includes a polishing machine, a first thickness metrology, and a second thickness metrology. The first thickness metrology is coupled with the polishing machine, and the second thickness metrology is also coupled with the polishing machine. The first thickness metrology and the second thickness metrology are in an in-situ manner, for measuring thickness for remaining first material layer and second material layer after polishing process.

Since the CMP apparatus of the invention includes the polishing machine and further includes the first thickness metrology and the second thickness metrology. Therefore, thickness of the polished wafers can be in-situ measured using the first thickness metrology and the second thickness metrology, and the measured results are fed back to a next wafer or to a next polishing process on the same wafer. As a result, the polishing parameters can be adjusted in real-time manner, so as to reduce the thickness difference of film layers between the wafers.

The invention provides a CMP process. In the CMP process, a wafer is first provided. On the wafer, the wafer has a first material layer with at least one opening. A lining layer is formed over a surface of the opening and the first material layer. A second material is formed over the lining layer to fully fill the opening. Then, a first polishing step is performed, to remove a portion of the second material layer other than the opening until the lining layer is exposed. A first thickness measuring step is in-situ performed for measuring the thickness of the remaining second material layer. Then, a second polishing step is performed, to remove a portion of the lining layer other than the opening and the second material layer until the first material layer is exposed. A second thickness measuring step is in-situ performed for measuring the thickness of the remaining first material layer.

The invention also provides a CMP process. In the CMP process, a plurality of wafers are first provided, wherein each of the wafers has been formed with a structure having a first material layer with at least an opening, a lining layer formed over a surface of the opening and the first material layer, and a second material layer being formed over the lining layer and fully filling the opening. Then, a first polishing step is performed on an ith wafer, to remove a portion of the second material layer other than the opening until the lining layer is exposed. A first thickness measuring step is in-situ performed for measuring the thickness of the remaining second material layer to obtain a first polishing parameter. Then, a second polishing step is performed on the ith wafer, to remove a portion of the lining layer other than the opening and the second material layer until the first material layer is exposed. A second thickness measuring step is in-situ performed for measuring the thickness of the remaining first material layer, so as to obtain a second polishing parameter. The first polishing step and the second polishing step are performed on a (i+1)th wafer, wherein the first polishing parameter and the second polishing parameter are respectively fed back to the first polishing step and the second polishing step on the (i+1)th wafer.

The invention further provides a CMP polishing process. In the CMP process, a plurality of wafers are first provided, wherein each of the wafers has been formed with a structure having a first material layer with at least an opening, a lining layer formed over a surface of the opening and the first material layer, and a second material layer being formed over the lining layer and fully filling the opening. Then, a first polishing step is performed on an ith wafer, to remove a portion of the second material layer other than the opening until the lining layer is exposed. A first thickness measuring step is performed for measuring the thickness of the remaining second material layer to obtain a first polishing parameter. And then, a second polishing step is performed on the ith wafer, to remove a portion of the lining layer other than the opening until the first material layer is exposed. A second thickness measuring step is in-situ performed for measuring the thickness of the remaining first material layer, so as to obtain a second polishing parameter. Wherein, the first polishing parameter is fed back for use during the second polishing step.

In the polishing step of the invention, since the polishing parameter obtained from the measuring step is fed back to the next wafer or the next polishing step on the same wafer, the polishing parameter can be adjusted in real-time. As a result, the thickness difference for the film layers between the wafers can be reduced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a process flow chart, schematically illustrating a CMP process on a metal interconnect structure, according to a preferred embodiment of the invention.

FIGS. 2A-2C are cross-sectional views, schematically illustrating the structure under the CMP process in FIG. 1.

FIG. 3 is a process flow chart, schematically illustrating a CMP process on a metal interconnect structure, according to another preferred embodiment of the invention.

### DESCRIPTION OF THE PREFERRED EMBODIMENTS

In the invention, the CMP apparatus at least includes a polishing machine, a first thickness metrology and a second thickness metrology. The first thickness metrology is connected with the polishing machine, and the second thickness metrology is also connected with the polishing machine.

In one preferred embodiment, the first thickness metrology is, for example, a metal thickness metrology, and the second thickness metrology is, for example, a dielectric thickness metrology. The metal thickness metrology uses, for example, the property that the laser light produces a reflection wave at the interface between different material, such as the interface between the metal layer and the dielectric layer, so as to measure the thickness. The dielectric thickness metrology uses, for example, the optical properties of refraction and reflection to measure the film thickness.

Particularly, the foregoing first thickness metrology and the second thickness metrology respectively in-situ measure the thickness of the remaining first material layer and the second material layer. In detail, the first thickness metrology and the second thickness metrology respectively record the thickness of the first material layer and the second material layer after polishing. And then, the two polishing parameters obtained from the thickness are fed back to the next wafer, or fed back to another polishing step on the same wafer. In the first preferred embodiment, the foregoing first material layer is, for example, the metal layer, and the second material layer is for example the dielectric layer.

Since the CMP apparatus of the invention includes the polishing machine but also includes the first thickness metrology and the second thickness metrology, the wafer can be in-situ measured by the first thickness metrology and the second thickness metrology after polishing the wafer. The measured results are fed back to the next wafer or another polishing step in the same wafer. The polishing parameters can be adjusted in real-time, so that the film thickness difference between the wafers can be reduced.

The CMP process using the foregoing CMP apparatus of the invention is described as follows. In the following embodiment, the process for forming the interconnect structure is used for descriptions about the CMP apparatus that is applied to the CMP process. However, the invention is not limited to this application. The invention can also be used in other process to fill the opening. In the process of interconnect structure, the first material layer is metal layer and the second material layer is the dielectric layer.

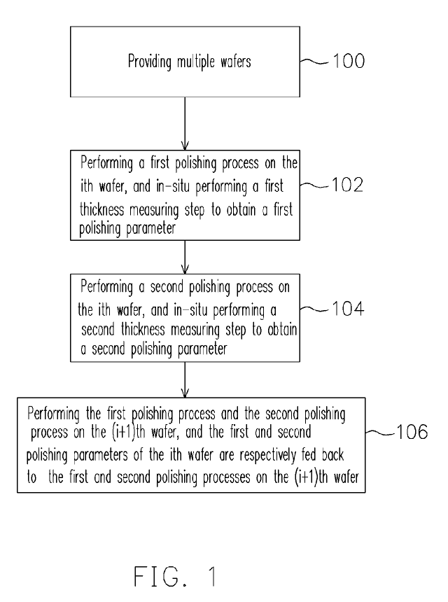

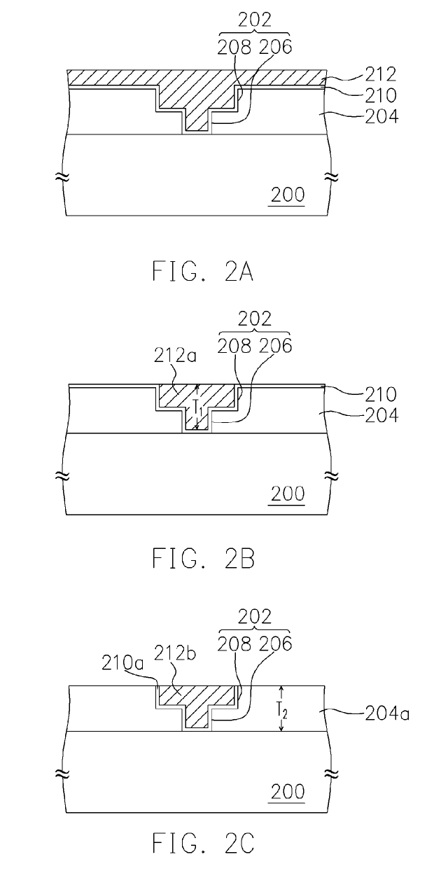

FIG. 1 is process chart, schematically illustrating the CMP process applied on fabricating an interconnect structure, according to the preferred embodiment of the present invention. FIGS. 2A-2C are cross-sectional views, schematically illustrating the wafer structure when performing the process in FIG. 1.

Referring to FIGS. 1 and 2A, a number of wafer 200 are provided, in which each of the wafers 200 has been formed with a dielectric layer 204 having at least one opening 202 (step 100). In the embodiment, multiple device structures (not shown) have been formed on the wafer 200, and the opening 202 exposes a conductive region. The conductive region includes, for example, the source/drain region, the gate electrode, the interconnect structure. In this embodiment, the opening 202 is formed by, for example, the contact opening 206 at the lower portion and the trench 208 at the upper portion.

Then, in FIG. 2A, a lining layer 210 is formed on a surface over the opening 202 and the dielectric layer 204, and a metal layer 212 is formed on the lining layer 210 with full filling the opening 202. Wherein, the lining layer 210 is formed from, for example, titanium nitride or other suitable material. The metal layer 212 is formed from, for example, tungsten or other suitable conductive material. The method for forming the metal layer 212 includes for example the chemical vapor deposition.

In FIG. 1 and FIG. 2B, a first polishing process is performed on the ith wafer 200, so that a portion of the metal layer 212 other than the opening 202 is removed, until the lining layer 210 is exposed. The remaining metal layer becomes the metal layer 212a. And, after removing the portion of the metal layer 212 other than the opening 202, a first thickness measurement is in-situ performed to measure the thickness T1 of the remaining metal layer 212a, so as to obtain a first polishing parameter (step 102). Step 102 can be, for example, performed in the CMP apparatus of the invention. That is, the polishing machine is used to polish the metal layer 212, and the metal thickness metrology is used to measure the thickness of the metal layer 212a. In addition, for another embodiment, the step 102 can be performed in a CMP apparatus just including the polishing machine and the metal thickness metrology without including the dielectric thickness metrology.

Particularly, in step 102, according to the thickness T1 obtained from the first thickness measuring step, it can be derived out about the metal thickness having been removed in the first polishing step. In addition, the consuming time for the polishing is considered, and then the parameters such as polishing rate in the first polishing step can be derived out. Or, the measured thickness T1 can be used to derive out about the resistance of the metal layer 212a.

Then, referring to FIG. 1 and FIG. 2C, the second polishing step is performed on the ith wafer 200, so that a portion of the metal layer 212a and the lining layer 210 other than the opening 202 is removed until the dielectric layer 204 is exposed and the metal layer 212b and the lining layer 210a are thereby formed. Since a portion of the dielectric layer 204 is also removed during performing the second polishing step, it becomes the dielectric layer 204a. After removing the portion of the metal layer 212a and the lining layer 210 other than the opening 202, a second thickness measuring step is in-situ performed to measure the thickness T2 of the remaining dielectric layer 204a, so as to obtain the second polishing parameter (step 104). Wherein, the step 104, for example, is performed under the CMP apparatus of the invention. That is, the polishing machine is used, in which the metal layer 212a and the lining layer 210 are polished with the slurry in difference from the slurry used in step 102. Also and, the dielectric thickness metrology is used to measure the thickness of the dielectric layer 204a. In addition, in another embodiment, the step 104 can be performed in the CMP apparatus just including the polishing machine and the dielectric thickness metrology without including the metal thickness metrology.

Particularly, in step 104, according to the thickness T2 obtained from the second thickness measuring step, it can similarly be derived out about the parameters such as polishing rate in the second polishing step. The measured thickness T2 can be used to derive out about the thickness of the metal layer, and then obtain the resistance of the metal layer.

In further another embodiment, when the first polishing step and the second polishing step are performed in completion on the ith wafer, the obtained polishing parameters can be fed back for the (i+1)th wafer, so as to adjust the polishing parameters in real-time and thereby to reduce the thickness difference between the wafers. The detail is described as follows.

Referring to FIG. 1, when the first polishing step (step 102) and the second polishing step (step 104) are performed in completion on the ith wafer, the first polishing step and the second polishing step are performed on the (i+1)th wafer (step 106). Particularly, while the first polishing step and the second polishing step are performing on the (i+1)th wafer (step 106), the first polishing parameter and the second polishing parameter obtained from the ith wafer are referenced to determine the polishing time, which is fed back in use. As a result, the metal layer of the (i+1)th wafer after completion of the step 106 has a thickness similar to the thickness of the metal layer of the ith wafer. This can improve the stability of metal resistance between the wafers.

In addition, while the first polishing step and the second polishing step are performing on the (i+1)th wafer (step 106), a third thickness measuring step and the fourth thickness measuring step can be in-situ performed, to measure the thickness of the remaining dielectric layer and the metal layer. The polishing parameters are further fed back to (i+2)th wafer in use for the first polishing step and the second polishing step. In other words, the obtained polishing parameters of each wafer after polishing can be fed back to the next wafer for use in real-time. Or, after collecting polishing parameters of several wafers, a result from statistic analysis can be fed back to the subsequent wafer for use. Therefore, it can be effectively reduced for the thickness difference of film layer of the wafers by using the method of the invention, and thereby the resistance stability of the metal layer between wafers is improved.

In another embodiment of the invention, after the foregoing step 100, the subsequent polishing step and measuring step are described as follows.

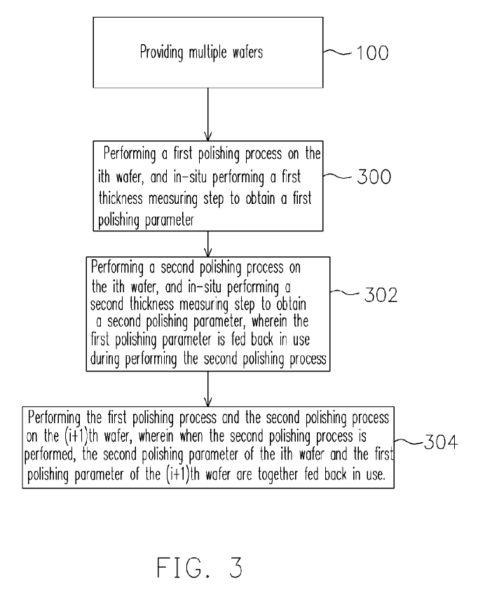

In FIG. 2B and FIG. 3, after the foregoing step 100, a first polishing step is performed on the ith wafer 200, to remove a portion of the metal layer 212 other than the opening 202, until the lining layer 210 is exposed, so as to form the metal layer 212a. In addition, after removing the portion of the metal layer 212 other than the opening 202, a first thickness measuring step is performed to measure the thickness T1 of the remaining metal layer 212a and obtain a first polishing parameter (step 300). Wherein, the step 300 is performed, for example, in the CMP apparatus of the invention. That is, the polishing machine is used to polish the metal layer 212, and the metal thickness metrology is used to measure the thickness of the metal layer 212a. In addition, in further another embodiment, the step 300 can be performed in a CMP apparatus just including the polishing machine and the metal thickness metrology without including the dielectric thickness metrology. In addition, in further another embodiment, the step 300 includes, for example, polishing the metal layer 212 in a CMP apparatus just including the polishing machine, and the thickness T1 of the metal layer 212a is measured in another thickness metrology.

After then, in FIG. 2C and FIG. 3, a second polishing step is performed on the ith wafer 200, so as to remove a portion of the metal layer 212a and the lining layer 210 other than the opening 202, until the dielectric layer 204 is exposed, so as to form the metal layer 212b and the lining layer 210a. Since a portion of the dielectric layer 204 is also removed during the second polishing step, the dielectric layer becomes the dielectric layer 204a. In addition, after the portion of the metal layer 212a and the lining layer 210 other than the opening 202 is removed, a second thickness measuring step is in-situ performed to measure the thickness T2 of the remaining dielectric layer 204a and obtain the second polishing parameter (step 302). Particularly, in the step 302, the polishing time used in the second polishing step is determined according to the first polishing parameter obtained in step 300. As a result, the thickness of the remaining metal layer 212b can be effectively controlled.

Also referring to FIG. 3, in further another embodiment, when the first polishing step (step 300) and the second polishing step (step 302) are performed in completion on the ith wafer, the first polishing step and the second polishing step can be performed on the (i+1)th wafer (step 304). Particularly, while performing the second polishing step (step 304) on the (i+1)th wafer, the second polishing parameter obtained from the ith wafer and the first polishing parameter obtained from the (i+1)th wafer are together used to determine the polishing time that is fed back in use. As a result, the thickness of the metal layer on the (i+1)th wafer after the step 304 is similar to the thickness of the metal layer on the ith wafer, so that the resistance stability between the wafers can be improved.

Moreover, in the embodiment, while performing the second polishing step on the (i+1)th wafer (step 304), a third thickness measuring step can be in-situ performed to measure the thickness of the remaining dielectric layer and the obtained polishing parameters are fed back in use for the second polishing step on the (i+2)th wafer. In other words, the polishing parameter of each wafer after the polishing step can be fed back in use for the next wafer. Or, after collecting polishing parameters of several wafers, a result from statistic analysis can be fed back to the subsequent wafer for use. Therefore, the thickness difference of film layer between wafers can be effectively reduced, by using the method of the invention, and whereby the resistance stability of the metal layer between wafers is improved.

In summary, the invention at least includes the advantages as follows.

1. Since the CMP apparatus of the invention includes not only the polishing machine but also a first thickness metrology and a second thickness metrology. As a result, the wafer, after polishing, can be in-situ measured by the first thickness metrology and the second thickness metrology, and the measuring result is fed back to the wafer or to another polishing step on the same wafer. Thereby, the polishing parameter can be adjusted in real-time, so as to reduce the thickness difference of film layers between the wafers.

2. In the polishing process of the invention, the polishing parameters obtained from the measuring steps are fed back to the next wafer or to another polishing step on the same wafer. Thereby, the polishing parameter can be adjusted in real-time, so as to reduce the thickness difference of film layers between the wafers.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A chemical mechanical polishing (CMP) apparatus, at least comprising:
a polishing machine;
a first thickness metrology, coupled to the polishing machine; and
a second thickness metrology, coupled to the polishing machine,
wherein the first thickness metrology and the second thickness metrology are used to in-situ measure a thickness for a first material layer and a second material layer in remaining after polishing process.

2. The CMP apparatus of claim 1, wherein the first thickness metrology and the second thickness metrology include a metal thickness metrology and a dielectric thickness metrology.

3. The CMP apparatus of claim 1, wherein the first thickness metrology and the second thickness metrology respectively record the thickness of the first material layer and the second material layer in a same wafer, and the two thickness are fed back in use to a next wafer.

4. The CMP apparatus of claim 1, wherein the first thickness metrology and the second thickness metrology respectively record the thickness of the first material layer and the second material layer in a same wafer, and the two thickness are fed back in use for another polishing step.

5. A chemical mechanical polishing (CMP) process, comprising:
providing a wafer, wherein the wafer has a first material layer with at least one opening, a lining layer is formed over a surface of the opening and the first material layer, wherein a second material is formed over the lining layer to fully fill the opening;
performing a first polishing step, to remove a portion of the second material layer other than the opening until the lining layer is exposed, wherein a first thickness measuring step is in-situ performed to measure a thickness of the remaining second material layer; and
performing a second polishing step, to remove a portion of the lining layer other than the opening and the second material layer until the first material layer is exposed, and a second thickness measuring step is in-situ performed to measure a thickness of the remaining first material layer.

6. The CMP process of claim 5, wherein the first material layer includes a dielectric layer and the second material layer includes a metal layer.

7. The CMP process of claim 5, wherein the opening is composed of a contact opening as a lower part and a trench as an upper part.

8. A chemical mechanical polishing (CMP) process, comprising:
providing a plurality of wafers, wherein each of the wafers has a first material layer with at least one opening, a lining layer is formed over a surface of the opening and the first material layer, and a second material is formed over the lining layer to fully fill the opening;
performing a first polishing step on an ith wafer of the wafers, to remove a portion of the second material layer other than the opening until the lining layer is exposed, wherein a first thickness measuring step is in-situ performed to measure a thickness of the remaining second material layer and a first polishing parameter is obtained; and
performing a second polishing step on the ith wafer, to remove a portion of the lining layer other than the opening and the second material layer until the first material layer is exposed, wherein a second thickness measuring step is in-situ performed to measure a thickness of the remaining first material layer and a second polishing parameter is obtained; and
performing the first polishing step and the second polishing step on an (i+1)th wafer of the wafers, wherein the first polishing parameter and the second polishing parameter obtained from the ith wafer are respectively referenced in the first polishing step and the second polishing step on an (i+1)th wafer.

9. The CMP process of claim 8, while performing the first polishing step on the (i+1)th wafer, further comprising performing a third thickness measuring step for measuring a thickness of the remaining second material layer to obtain a third polishing parameter, and while performing the first polishing step on an (i+2)th wafer of the wafers, the third polishing parameter is fed back in use.

10. The CMP process of claim 8, while performing the second polishing step on the (i+1)th wafer, further comprising performing a fourth thickness measuring step for measuring a thickness of the remaining first material layer to obtain a fourth polishing parameter, and while performing the second polishing step on an (i+2)th wafer of the wafers, the fourth polishing parameter is fed back in use.

11. The CMP process of claim 8, wherein the first material layer includes a dielectric layer and the second material layer includes a metal layer.

12. The CMP process of claim 8, wherein the opening is composed of a contact opening as a lower part and a trench as an upper part.

13. A chemical mechanical polishing (CMP) process, comprising:
providing a plurality of wafers, wherein each of the wafers has a first material layer with at least one opening, a lining layer is formed over a surface of the opening and the first material layer, and a second material is formed over the lining layer to fully fill the opening;
performing a first polishing step on an ith wafer of the wafers, to remove a portion of the second material layer other than the opening until the lining layer is exposed, wherein a first thickness measuring step is performed to measure a thickness of the remaining second material layer and a first polishing parameter is obtained; and
performing a second polishing step on the ith wafer, to remove a portion of the lining layer other than the opening and the second material layer until the first material layer is exposed, wherein a second thickness measuring step is in-situ performed to measure a thickness of the remaining first material layer and a second polishing parameter is obtained, and the first polishing parameter is fed back in use while the second polishing step is performed.

14. The CMP process of claim 13, after the second polishing step, further comprising performing the first polishing step and the second polishing step on an (i+1)th wafer, wherein while the first polishing step and the second polishing step are performing, the second polishing parameter obtained from the ith wafer and the first polishing parameter obtained from the (i+1)th wafer are together fed back in use.

15. The CMP process of claim 14, while performing the second polishing step on the (i+1)th wafer, further comprising in-situ performing a third thickness measuring step to measure a thickness of the remaining first material layer and a third polishing parameter is obtained, and the third polishing parameter is fed back in use while performing the second polishing step on the (i+2)th wafer.

16. The CMP process of claim 13, wherein the first thickness measuring step is in-situ performed.

17. The CMP process of claim 13, wherein the first material layer includes a dielectric layer and the second material layer includes a metal layer.

18. The CMP process of claim 13, wherein the opening is composed of a contact opening as a lower part and a trench as an upper part.
